(19) United States
(12) Patent Application Publication
(10) Pub. No.: US 2026/0321963 A1
(43) Pub. Date: Oct. 15, 2026

(54) ON-CHIP ANTENNA ARRAY AND METHODS OF MANUFACTURING THEREOF

(71) Applicant: Teknologian tutkimuskeskus VTT Oy, Espoo (FI)

(72) Inventors: Christoffer KAUPPINEN, Espoo (FI); Mikko VARONEN, Espoo (FI)

(21) Appl. No.: 19/643,481

(22) Filed: Apr. 9, 2026

(30) Foreign Application Priority Data
Apr. 10, 2025 (FI) 20253128

(51) Int. Cl. H01Q 1/22; H10P 58/00; H10P 72/70

(52) U.S. Cl. CPC H01Q 1/2283; H10P 58/00; H10P 72/7416

(57) ABSTRACT

An on-chip antenna comprises an array of radiating elements arranged on a first surface of a planar substrate to radiate electromagnetic radiation at a frequency in a range from about 100 GHz to 1 THz, and an radiation extraction coating arranged on an opposite surface of the planar substrate, wherein a thickness and a refractive index of the radiation extraction coating are selected such that the electromagnetic radiation reflected from an interface between the planar substrate and the radiation extraction coating and the electromagnetic radiation reflected from an interface between the radiation extraction coating and a surrounding medium are minimized, and are substantially out of phase and cancel each other in the substrate at least partially, resulting in a higher extraction of the electromagnetic radiation to the surrounding medium.

### TECHNICAL FIELD

The present invention relates to on-chip antenna arrays.

### BACKGROUND

Terahertz frequency range is typically considered to be between 100 GHz to 10 THz corresponding to wavelengths between 3 mm and 30 μm. The high frequency and short wavelength allow for e.g. high data-transmission rates, high spatial resolution and limited material penetration which find utility in various applications such as wireless communication (e.g. 6G), medical imaging and surface or near-surface material spectroscopy.

On-chip antenna arrays are antenna arrays fabricated directly onto semiconductor substrates. Control of the phase of each antenna array element allows for steering of the beam direction, which is a pre-requisite for using the on-chip antenna array in e.g. 6G and imaging application. In such applications, it is desirable that the array be as dense as possible because this allows for precise control over the radiation pattern and increased efficiency in directing energy. However, at terahertz frequencies, the electromagnetic radiation couples to the substrate material and only a fraction of the radiation is emitted out. The radiation extraction efficiency could be improved by using on-chip lenses, but their relatively large size limits the fabrication of sufficiently dense antenna arrays for said applications.

### BRIEF DESCRIPTION

An object of the present invention is thus to provide an apparatus which overcomes the above problem or at least alleviates the problem. The object of the invention is achieved by an on-chip antenna array and manufacturing methods disclosed in the independent claims. Embodiments of the invention are disclosed in the dependent claims.

An aspect of the invention is to provide an array of radiating elements on a first surface of a planar substrate to radiate electromagnetic radiation at a frequency in a range from about 100 GHz to 1 THz and provide a radiation extraction coating on an opposite surface of the planar substrate. A thickness and a refractive index of the radiation extraction coating are selected such that the electromagnetic radiation reflected from an interface between the planar substrate and the radiation extraction coating and the electromagnetic radiation reflected from an interface between the radiation extraction coating and a surrounding medium are substantially out of phase and cancel each other in the substrate, resulting in a higher extraction of the electromagnetic radiation to the surrounding medium.

Embodiments of the invention can provide efficient radiation extraction of terahertz frequency range electromagnetic radiation for on-chip antenna array while allowing high density of the on-chip antenna array.

Further aspects of the invention are methods of manufacturing the on-chip antenna array according to embodiments of the invention.

Still another aspect of the invention is an extraction tape for use in the on-chip antenna or in manufacturing methods according to embodiments of the invention.

### BRIEF DESCRIPTION OF THE DRAWINGS

In the following the invention will be described in greater detail by means of preferred embodiments with reference to the attached drawings, in which

FIG. 1 is a cross-sectional view illustrating a prior art on-chip radiating element radiating towards substrate and surrounding medium.

FIG. 2 is a cross-sectional view illustrating the problem that, for small wavelengths and high frequencies, an antenna spacing in an antenna array will become so small that the physical placing of prior art discrete lenses on the antenna array would be extremely difficult or infeasible..

FIG. 3 is a cross-sectional view illustrating an example of an on-chip antenna array according to an embodiment.

FIG. 4 is a cross-sectional view illustrating the working principle of an on-chip antenna array illustrated in FIG. 3.

FIG. 5 is a cross-sectional view illustrating an extraction tape of an on-chip antenna array of FIG. 3 according to an embodiment.

FIG. 6 is a cross-sectional view illustrating an extraction tape of an on-chip antenna array of FIG. 3 according to another embodiment.

FIG. 7 illustrates process steps together with cross-sectional view for method of manufacturing of an on-chip antenna array of FIG. 3 according to an embodiment.

FIG. 8 illustrates process steps together with cross-sectional view for method of manufacturing of an on-chip antenna array of FIG. 3 according to another embodiment.

FIG. 9. and FIG. 10. are exemplary graphs illustrating experimental measurement results of radiation extraction efficiency vs. frequency of a silicon die with and without a radiation extraction coating formed with the extraction tape.

### DETAILED DESCRIPTION

The following embodiments are exemplary. Although the description may refer to “an”, “one”, or “some” embodiment(s) in several locations, this does not necessarily mean that each such reference is to the same embodiment(s), or that the feature only applies to a single embodiment, for example. Single features of different embodiments may also be combined to provide other embodiments. Different embodiments and examples may be described below using single units, models and equipment, without restricting the embodiments/examples to such a solution. Generally, all terms and expressions used should be interpreted broadly and they are intended to illustrate, not to restrict, the embodiments. The figures only show components necessary for understanding the various embodiments. The number and/or configuration of the various elements, and generally their implementation, could vary from the examples shown in the figures, for instance. It should be noted that the use of the embodiments described herein is not limited to devices or systems employing any specific frequency for example.

On-chip antenna arrays are antenna arrays comprising a plurality of radiating elements which have been typically fabricated on a semiconducting substrate. The radiating elements of the on-chip antenna array may be operating at terahertz frequency range which is typically considered to be from 0.1 THz to 10 THz corresponding to wavelengths between 3 mm and 30 μm. Due to the short wavelength, the dimensions of the radiating elements may be decreased significantly leading to high miniaturization potential for the on-chip antenna array. The on-chip antenna array may also comprise the necessary circuitry for individual phase control (or time delay) of each radiating element. In such case, the on-chip antenna array may be called on-chip phased antenna array. The phase control allows for creating constructive or destructive interference of the radiated (emitted) electromagnetic waves in certain direction thereby allowing the control of the direction of the beam of electromagnetic waves emitted by the on-chip antenna array (i.e. allowing beam steering). Beam steering is especially useful in various terahertz applications such as wireless communication (e.g. 6G), imaging (e.g. medical imaging, non-destructive testing, security screening), material spectroscopy (e.g. terahertz spectroscopy, chemical sensing) and radar applications (e.g. automotive radar for assisted or self-driving applications). In such applications, the density of the radiating elements (i.e. the number of radiating elements per unit area) of the on-chip antenna array contributes to the precision of control over the radiation pattern and increased efficiency in directing the radiation in certain direction, and this, in turn, translates to e.g. higher spatial resolution. Moreover, arranging the radiating elements of the on-chip antenna array such that the distance between them is equal to, or less than, half of the wavelength of the radiated electromagnetic wave enables suppression of grating lobes (i.e. undesirable constructive interference in certain directions). Hence, it is often beneficial to maximize the density of the radiating elements of the on-chip antenna array operating at terahertz frequency range.

The direction of radiation from the radiating element may be simultaneously towards the substrate and away from the substrate (i.e. towards the surrounding medium). This is exemplified in FIG. 1, which shows a cross-sectional image of a prior art on-chip radiating element 102 radiating towards substrate 101 (radiation lobe 104) and surrounding medium 100 (radiation lobe 103). In many situations, it is preferrable that the radiating element 102 is radiating mainly towards the surrounding medium 100 and not towards the substrate 101 i.e. that the radiation is extracted efficiently from the radiating element 102. However, the extraction efficiency is often poor due to coupling of the radiation to the substrate 101 as exemplified in FIG. 1. wherein the sizes of the radiation lobes 103 and 104 indicate the amount of radiated power. Quantitatively, the radiation extraction efficiency, i.e. the ratio of power of extracted radiation Pₑₓₜ (i.e. the amount of radiated power in radiation lobe 103) to the total radiated power Pₜₒₜ, (i.e. the total amount of power in radiation lobes 103 and 104), may be estimated using equation

Pₑₓₜ/Pₜₒₜ=(εₛᵤᵣᵣ/ε_{subst})^{3/2} (1)

wherein εₛᵤᵣᵣ is the relative permittivity of the surrounding medium 100, and ε_{subst} relative permittivity of the substrate 101. Hence, in a situation where the radiating element 102 is arranged on surface of the substrate, the surrounding medium 100 is air with relative permittivity of 1, and the substrate 101 is silicon with relative permittivity of 11.7, the fraction of power of extracted radiation may be only approximately 3% of the total radiated power meaning that approximately 97% of the total radiated power is coupled (i.e. lost) into the substrate. In other words, the radiation extraction efficiency of the on-chip antenna array in such a scenario is very poor.

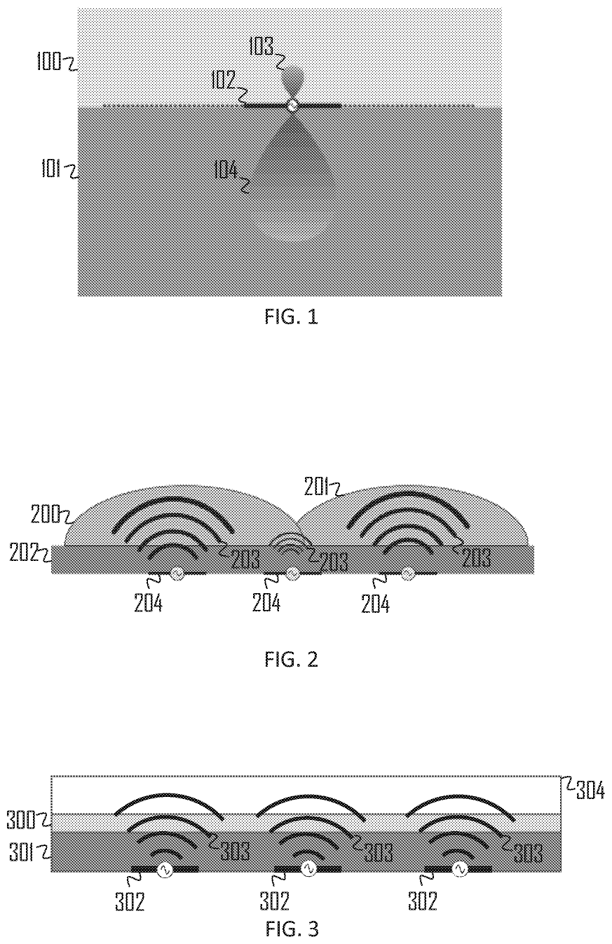

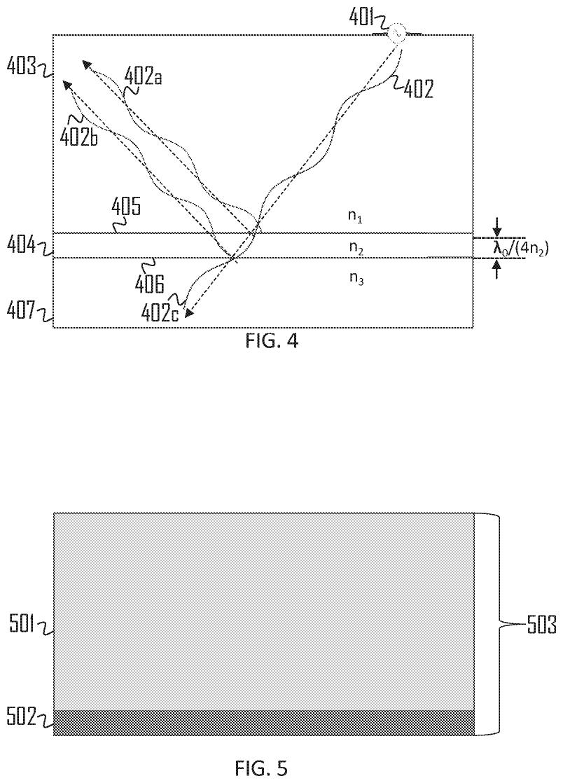

In order to compensate for this effect, on-chip lenses have been proposed. In addition to the refractive index of the substrate and surrounding medium, the radiation extraction efficiency is also determined by the angle of the incidence of the electromagnetic wave at the interface of the two media (i.e. at the interface of substrate and surrounding medium) such that the more orthogonal the incident wave is to the interface, the more likely it is to be extracted (i.e. outcouple) from the substrate. Thus, by providing a hemispherical protrusion on the substrate, wherein the protrusion is of the same material as the substrate, or has the same refractive index, the curvature of the substrate surface is manipulated in a way that a larger fraction of the incident electromagnetic wave will arrive orthogonally at the interface thereby promoting the radiation extraction efficiency. However, a problem with this solution is that the on-chip lenses cannot be designed, neither feasibly fabricated small enough to enable arranging the radiating elements of the on-chip antenna array operating at terahertz frequency range at a spacing of half the wavelength of the radiated electromagnetic waves. To elaborate, at terahertz frequency range the half wavelength spacing becomes so small that arranging individual lenses with the required half wavelength spacing becomes hard or infeasible. For example, even at the long wavelength end of the THz spectrum, that is 100 GHz, the half wavelength spacing is approximately 1.5 mm. Therefore, the on-chip lenses for increasing radiation extraction efficiency for a phased antenna array operating at 100 GHz must have a maximum diameter of 1.5 mm. Fabricating lenses with such a small diameter, with precision required in optics, of high refractive index materials and preferably of the substrate material like Si, Ge and GaAs, is not feasible, since fabricating such small lenses of these high refractive index materials raises the complexity and the cost enormously. Due to this reason, there are prior art solutions where the lenses are micromachined on to the substrate material itself, thus making the lens side of the die having a complex topography which is difficult to fabricate as complex microfabrication methods are required. Such solutions involving micromachined lenses into the substrate are complicated and non-standard in semiconductor electronics fabrication and raise the fabrication cost tremendously. FIG. 2 shows a cross-sectional view illustrating the problem arising when one attempts to place too large on-chip lenses 200, 201 on a substrate 202 with an array of radiating elements 204 radiating electromagnetic waves 203 at terahertz frequency range. The radiating elements 204 shall be arranged at a very small spacing equal to, or less than, half of the wavelength of the radiated electromagnetic waves 203. Hence, the efficient extraction of electromagnetic waves 203 from all the radiating elements 204 is not possible (cf. the radiating element 204 in the middle of the substrate 202, which does not have a corresponding on-chip lens). To summarize, the use of on-chip lenses is not a feasible way to fabricate the on-chip antenna array operating at terahertz frequency range with radiating elements 204 arranged at half wavelength spacing. According to an aspect of the invention exemplified in FIG. 3, an on-chip antenna array comprises an array of radiating elements 302 arranged on a first surface of a planar substrate 301 to radiate electromagnetic radiation 303 (i.e. electromagnetic waves) at a frequency in a range from about 100 GHz to 1 THz, and an radiation extraction coating 300 arranged on an opposite surface of the planar substrate 301. A thickness and a refractive index of the radiation extraction coating 300 may be selected such that the electromagnetic radiation 303 reflected from an interface between the planar substrate 301 and the radiation extraction coating 300 and the electromagnetic radiation 303 reflected from an interface between the radiation extraction coating 300 and a surrounding medium 304 are reduced or minimized, and are substantially out of phase and cancel each other in the substrate 301 at least partially, resulting in a higher extraction of the electromagnetic radiation 303 to the surrounding medium 304. The working principle of the above aspect of the invention is illustrated in FIG. 4 which shows electromagnetic radiation 303, 402 emitted from one radiating element 302, 401 of an on-chip antenna array arranged on the planar substrate 301, 403. As a result of the coupling of the electromagnetic radiation 303, 402 to the substrate 301, 403 (see discussion related to equation (1) above), most of the electromagnetic radiation 303, 402 emitted by the radiating element 302, 401 is radiated (i.e. propagated) towards the radiation extraction coating 300, 404 at the opposite surface of the planar substrate 301, 403. The radiation extraction coating 300, 404 on said opposite surface of the planar substrate 301, 403 has a thickness and a refractive index which enable achieving a higher extraction of the electromagnetic radiation (i.e. higher extraction efficiency) to the surrounding medium, than without the coating. The extraction efficiency may be maximized by exploiting interference cancellation and impedance matching as explained in the embodiments below.

In embodiments, the interference cancellation is enabled by selecting radiation extraction coating 300, 404 with thickness that is within a tolerance of an odd multiple of a quarter wavelength of the electromagnetic radiation in the radiation extraction coating 303, 402, the tolerance being preferably less than ±20%, more preferably ±10%, and even more preferably ±5%. Mathematically, this can be expressed as (without considering the tolerances):

tₑₓₜ≈(2*m−1)*λ₀/(4*n₂), (2)

wherein tₑₓₜ is thickness of the radiation extraction coating 300, 404, m is an integer larger than 0, λ₀ is the wavelength of the electromagnetic radiation in vacuum 303, 402, and n₂ is the refraction coefficient of the radiation extraction coating 300, 404. Selecting tₑₓₜ according to equation (2) ensures that a reflected electromagnetic wave 402a from substrate—radiation extraction coating interface 405 and reflected electromagnetic wave 402b from radiation extraction coating—surrounding medium interface 406 are out of phase and, hence, cancel each other out (at least partly) in the substrate thereby reducing the reflected power from the substrate—extraction coating interface back to the substrate and thus improving the extraction efficiency, as more power exits through the extraction coating to the surrounding medium. It may be beneficial to choose a low value for the integer m so that the absorption of the electromagnetic radiation 303, 402 to the radiation extraction coating 300, 404 is minimized. However, in certain scenarios, it may be more practical to choose a higher value for integer m: for example, if the wavelength of the electromagnetic radiation 303, 402 is very small, it may be necessary to use a higher value for integer m so as to not make the radiation extraction coating 300, 404 too thin and, hence, too fragile. Similarly, the tolerance for the thickness may be chosen based on e.g. manufacturing tolerance for the thickness of the radiation extraction coating 300, 404 and frequency of the electromagnetic radiation 303, 402. For example, if the frequency is at high end of the frequency range (i.e. 1 THz or close to 1 THz), the quarter wavelength of the electromagnetic radiation 303, 402 is very small, and it may be therefore impractical, or impossible, to achieve a tolerance of ±5% for the thickness of the radiation extraction coating and, hence, ±10%, or even ±20% tolerance may be used.

In embodiments, the impedance matching is enabled by selecting the material of the radiation extraction coating 300, 404, such that the refractive index n₂ of the radiation extraction coating 300, 404, is between the refractive index n₁ of the planar substrate 301, 403 and refractive index n₃ of surrounding medium 304, 407, preferably (or optimally) within a tolerance of a geometric mean of refractive indices n₁ and n₃

n₂≈(n₁*n₃)^{1/2}, (3)

the tolerance being preferably less than ±20%, more preferably ±10%, and even more preferably ±5%. As a non-limiting example, if the surrounding medium 304, 407 is air (i.e. n₃ is close to 1) and the planar substrate 301, 403 is silicon (i.e. n₁ is close to 3.5), then the optimal refractive index for the material of the radiation extraction coating 300, 404 is within a tolerance of the square root of the refractive index of silicon i.e. n₂≈1.87. Selecting the material for the extraction coating 300, 404 according to equation (3) ensures that the amount of total reflection due to mismatch between n₁ and n₃ is minimized, and, hence, the radiation extraction efficiency is increased. The total reflection may be estimated using the formula for reflectance in the case of Fresnel reflection:

R_{AB}=[(n_{A}−n_{B})/(n_{A}+n_{B})]², (4)

wherein R_{AB} is the reflection coefficient at the interface of materials A and B, and the n_{A} and n_{B} are the refraction coefficients of materials A and B, respectively. Using the equation (4) to continue the above non-limiting example calculation wherein the surrounding medium 304, 407 is air (i.e. n₃ is close to 1), the planar substrate 301, 403 is silicon (i.e. n₁ is close to 3.5) and the radiation extraction coating has an optimal refractive index of n₂≈1.87, we find that at both interfaces, i.e. the substrate-radiation extraction coating interface 405 and the radiation extraction coating-surrounding medium interface 406, approximately 9.2 % of the incident power will be reflected. In contrast, if there is no radiation extraction coating 300, 404 between the planar substrate 301, 403 and the surrounding medium 304, 407, approximately 30.8 % of the incident power would be reflected. In other words, impedance matching according to equation (4) allows for increase in radiation extraction efficiency. Furthermore, by implementing impedance matching together with interference cancellation (see discussion related to equation (2)), the performance of the radiation extraction coating can be improved even further.

As the radiation extraction coating 300, 404 is a planar coating applied uniformly on the planar substrate 301, 403, the radiating elements of the on-chip antenna array can be arranged at spacing −equal to, or less than, half of the wavelength of the radiated electromagnetic wave. In other words, unlike e.g. on-chip lenses discussed above wherein the dimensions of the lenses limit the density of the antenna array, the radiation extraction coating 300, 404 disclosed herein enables maximizing the density of the radiating elements of the on-chip antenna array while maintaining, or even improving, the extraction efficiency.

In embodiments, e.g., as exemplified in FIG. 5, the radiation extraction coating 300, 404 may be formed by an extraction tape 503 comprising a base layer 501 of polymeric material and an adhesive 502 layer between the planar substrate and the layer of polymeric material. For example, the polymeric material of the base layer may comprise polypropylene (polypropene), polyimide or polyethylene. The polymeric material of the base layer 501 may be also any other polymeric material which has a refraction index between the refraction indices of the planar substrate and the surrounding medium, or, preferably, refractive index value within a tolerance of an optimal value as determined using equation (3). If no suitable polymeric material exists, it is also possible that the polymeric material of the base layer 501 comprises a composite (i.e. a nanocomposite) of a polymer and a filler material. In this case, the purpose of the filler material is to modify the refraction index of the base layer 501 such that it is closer to the optimal value determined using equation (3). A non-limiting example of the filler material may be any inorganic material, for example barium titanate, titanium dioxide or zirconium dioxide. It is preferrable that the individual particles of the filler material are very small (e.g. nanoparticles) in order to improve homogeneity, and performance of the composite. The adhesive layer 502 of the extraction tape may be of any material which provides sufficient adhesion between the base layer 501 and the planar substrate while preferably being able to form a layer thin enough so as not to impact the electromagnetic radiation transmitted through it. It is also possible that the material of the adhesive layer 502 is selected such that it has a refractive index which matches the refractive index of the base layer 501 or is very close to it. It is also possible to select the refractive index of the adhesive layer such that it is between the refractive indices of the planar substrate and the base layer 501 of the extraction tape 503, preferably within a tolerance of the geometric mean of the refractive indices of the planar substrate and the base layer 501 of the extraction tape 503. Non-limiting examples of possible adhesive materials are acrylic adhesives, silicone adhesives and polyurethane adhesives.

In embodiments, the extraction tape 503 may serve also as a dicing tape. For this purpose, the thickness of the extraction tape may be selected such that it enables holding the wafer together during the cutting (i.e. dicing) step of the manufacturing process, The dicing step may be e.g. any wafer or planar substrate dicing process like mechanical blade dicing, laser dicing, or plasma dicing. In other words, in this embodiment, a larger value for the integer m of equation (4) may be chosen when determining the optimal thickness for the radiation extraction coating 300, 404.

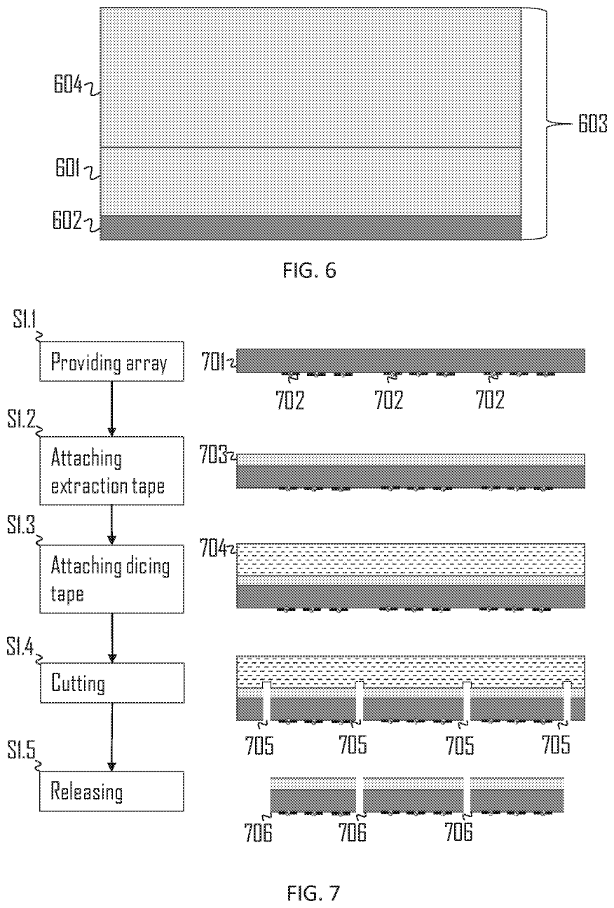

In alternative embodiments, e.g., as exemplified in FIG. 6, the extraction tape 503, 603 may comprise, in addition to the adhesive layer 502, 602 and the base layer 501, 601 serving as radiation extraction coating 300, 404, a layer serving as the dicing tape 604 on top of the base layer 501, 601, wherein the layer serving as the dicing tape 604 is releasable from the base layer 601 after the dicing has been completed. For the purpose of releasing the layer serving as the dicing tape 604 from the base layer 601, the interface between said layers 604, 601 may be modified so as to provide adhesion between said layers 604, 601 during the dicing step of the manufacturing process while also enabling releasing said layers from each other after the dicing step of the manufacturing process has been completed without causing the extraction coating to be released from the planar substrate. Said modification may be performed using any surface treatment, and/or adhesion promoter, and/or adhesive providing suitable level of bonding between said layers 604, 601. It is for example possible, that the adhesive is an UV-sensitive adhesive i.e. an adhesive for which the adhesive strength can be reduced by applying UV-radiation. In this case, the radiation extraction coating formed by the adhesive layer 602 and the base layer 601 may be cut through at least to the layer serving as dicing tape 604 during the dicing step of the manufacturing process. Typically, the blade goes into the dicing tape a little bit, not through it but bites into it. It is also possible that the dicing tape 604 comes already with an adhesive so no surface modification step for the interface of the dicing tape 604 and the base layer 601 is needed.

In alternative embodiments, the radiation extraction coating 300, 404 may be formed by the extraction tape 503 applied on the planar substrate 301, 407, as a separate step, prior to applying a dicing tape during a manufacturing process, the extraction tape 503 being left on the surface of the planar substrate 301, 407 after dicing and removal of the now individual dies from the dicing tape (i.e. after dicing step of the manufacturing process). The dicing tape may be applied on top of the extraction tape 503. To enable releasing of the dicing tape without releasing the extraction tape 503 from the planar substrate 301, 407, the dicing tape may comprise an adhesive layer for which the adhesive strength is smaller than the adhesive strength of the adhesive layer 502 of the extraction tape 503. For example, the dicing tape may comprise an adhesive layer with modifiable adhesive strength such as an UV-sensitive adhesive, i.e. an adhesive for which the adhesive strength can be reduced by applying UV-radiation, or a heat-sensitive adhesive, i.e. an adhesive for which the adhesive strength can be reduced by applying heat. If a modifiable adhesive is used for the dicing tape, the adhesive of the extraction tape 503 should be selected such that the modification method (e.g. UV-, or heat-treatment) does not affect its adhesive strength. In a further embodiment, the radiation extraction coating formed by the extraction tape 503 may be cut through to the dicing tape during the manufacturing process (i.e. during the dicing step of the manufacturing process).

In embodiments, the array of radiating elements may comprise a phased array of radiating elements. In such case, the phase of the electromagnetic waves of each radiating element of the array of radiating elements is individually adjustable. A segmented antenna array in which two or more antenna elements are fed by a single-phase shifter may also be used. The array of radiating elements may comprise radiating elements arranged in pairs, each pair forming a dipole antenna. In this case, the radiating elements of the pair of elements are symmetrically arranged in relation to each other, and the total length of the radiating elements is half of the wavelength of the electromagnetic waves emitted by the radiating elements. Alternatively, or additionally, it is possible that the radiating elements comprise a patch antenna, a slot antenna, a leaky-wave antenna, Yagi-Uda antenna, an aperture-coupled antenna, or any other antenna structure with ability to radiate at terahertz frequency range. Radiating elements may be of any sufficiently conductive material such as copper (Cu), aluminium (Al), gold (Au), molybdenum (Mo), tungsten (W) or titanium tungsten (TiW), or any combination thereof, or the radiating elements might be made from a sufficiently conductive ceramic, degeneratively doped semiconductor, or compound like TiN, NbN, or aluminium doped ZnO. Alternatively, radiating elements may also be formed by locally doping the semiconductor of the substrate with suitable dopant to increase its conductivity. The on-chip antenna array may further comprise components and circuitry required to enable individual adjustability of the phase of the radiating elements. Non-limiting examples of such include digital, analog, capacitive or micro-electro-mechanical system (MEMS) based phase shifters. It is also possible that components and circuitry required for generating, modulating, amplifying, and filtering the terahertz frequency range signal for the radiating elements are integrated together with the on-chip antenna array. Non-limiting examples of such components and circuitry are Complementary Metal-Oxide-Semiconductor (CMOS) oscillator and/or amplifier, Heterojunction Bipolar Transistor (HBT) and High Electron Mobility Transistor (HEMT) oscillator and/or amplifier, frequency multiplier, Resonant Tunneling Diode (RTD) and oscillator based thereon, or Gunn Diode and oscillator based thereon.

In embodiments, a distance between each radiating element of the array of radiating elements is no more than half of the wavelength of the electromagnetic waves. The advantages of such configuration have been discussed above. In another embodiment, the distance between each radiating element of the array of radiating elements is more than half of the wavelength of the electromagnetic waves (e.g. sparse antenna arrays).

In embodiments, the planar substrate 301, 407 may comprise a layer of semiconducting material. The semiconducting material may be, for example, silicon (Si), germanium (Ge) or gallium arsenide (GaAs) or any other suitable semiconductive material or any doped or undoped form thereof. In some embodiments, the planar substrate 301, 407 may comprise an insulating layer. The insulating layer may be e.g. a sapphire layer. The planar substrate may be also e.g. an engineered semiconductor wafer like a silicon on insulator (SOI) wafer, silicon on sapphire (SOS), or any other non-homogenous semiconductor wafer that comprises multiple material layers. The planar substrate maybe a semiconductor wafer or insulator wafer where multiple semiconductor materials like e.g. gallium nitride (GaN), aluminium nitride (AlN), aluminium gallium nitride (AlGaN), GaAs, aluminium gallium arsenide (AlGaAs), or any other semiconductor material have been grown epitaxially. Multiple epitaxial layers of said semiconductor materials maybe used on a wafer that functions as the planar substrate. It is also possible that the planar substrate comprises one or more material layers between the array of antenna elements and the layer of semiconducting material. In embodiments, the one or more material layers between the array of antenna elements and the layer of semiconducting material may include a dielectric layer, preferably an oxide of silicon (e.g. a silicon dioxide, SiO₂). However, if the oxide of silicon is not suited for the semiconducting layer due to e.g. poor interface quality (as is the case for Ge or GaAs semiconducting layers), the one or material layers may comprise a layer of aluminium oxide (Al₂O₃), or hafnium oxide (HfO₂). It is also possible that the one or more material layers may comprise an adhesion promoter to improve adhesion of the radiation extraction coating 300, 404 to the planar substrate. It should be understood that planar substrate does not necessarily mean that top and bottom surfaces are absolutely flat, as the antenna arrays and on-chip circuitry cause minor, typically micrometer or nanometer-scale deviations from ideally planar surface, but that substrate is macroscopically flat so that tape can be applied on the surface of the substrate.

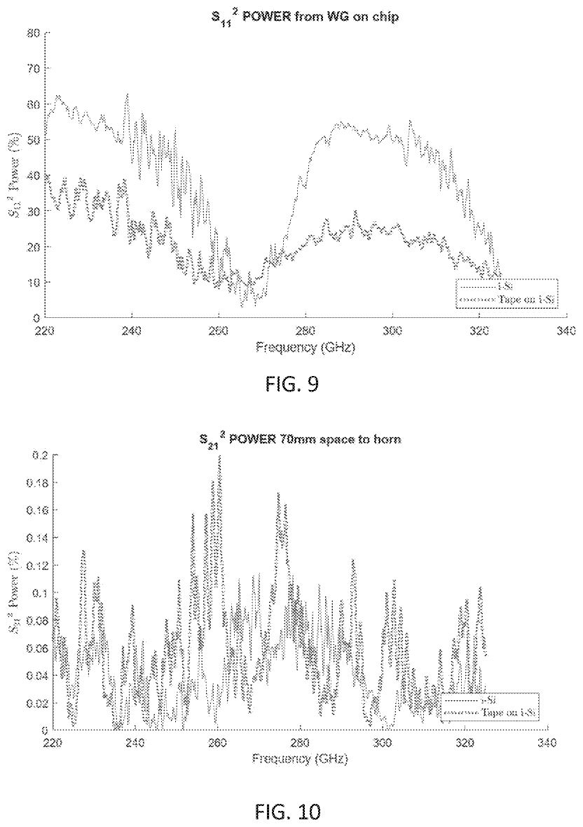

FIG. 9 and FIG. 10 show exemplary graphs of experimental measurement results of radiation extraction efficiency with and without the radiation extraction coating 300, 404 formed by an extraction tape. In the experimental setup, a waveguide (acting a radiating element) generating the electromagnetic radiation is arranged on the first surface of a silicon die (acting as the planar substrate) while the opposite surface of the silicon die is either left free of coating or coated with radiation extraction coating (i.e. coated with an extraction tape) and a receiving antenna is used to measure the electromagnetic radiation extracted from the opposite surface of the silicon die with/without the radiation extraction coating. The die is well separated from the receiving antenna, with at least 20 times λ₀ as separation so the radiation is well in the far-field. The graph in FIG. 9. shows the reflected power at frequency range of 220 to 325 GHz is suppressed on average approximately 46% when radiation extraction coating is applied on the silicon die, while the graph in FIG. 10. shows that the power transmitted to antenna simultaneously increases on average by approximately 42%. In other words, the radiation extraction efficiency is significantly increased by applying the radiation extraction coating according to the invention disclosed herein.

According to an aspect of the invention exemplified in FIG. 7 there is provided a method of manufacturing the on-chip antenna of above embodiments, wherein the method comprises
providing S1.1 at least one array of radiating elements 702 on a first surface of a planar substrate 701,
attaching S1.2 an extraction tape 703 on an opposite surface of the planar substrate 701 to form a radiation extraction coating 300, 404, the extraction tape 503, 703 having a base layer 501 of polymeric material and an adhesive layer 502 between the planar substrate 701 and the base layer 501 of polymeric material,
attaching S1.3 a dicing tape 704 on the radiation extraction coating 300, 404,
cutting S1.4 through the planar substrate 701 and the radiation extraction coating 300, 404 in order to form dies having the radiation extraction coating 300, 404; and
releasing S1.5 the dies 706 having the radiation extraction coating 300, 404 from the dicing tape 704.

In the first step (S1.1), the at least one array of radiating elements 702 may be provided for example by first using physical vapor deposition (such as sputtering or evaporation), chemical vapor deposition, electroplating or atomic layer deposition of any sufficiently conductive material, non-limiting examples of which are copper (Cu), aluminium (Al), gold (Au), molybdenum (Mo), tungsten (W) or titanium tungsten (TiW), followed by photolithography and wet or dry etching to form the geometry of the array of radiating elements, or a sequential combination of these with or without other microfabrication methods. The microfabrication methods may comprise any integrated circuit fabrication processes, such as complementary metal-oxide-semiconductor (CMOS) or silicon-germanium bipolar CMOS (SiGe BiCMOS) processes. It is also possible that the array of radiating elements 702 is formed using any direct patterning method capable of sufficiently high resolution such as high-resolution inkjet printing (e.g. electrohydrodynamic inkjet printing, piezoelectric inkjet printing) together with nanoparticle based conductive inks, or by locally doping the semiconductor of the planar substrate, or any other method compatible with microelectronics processing, or any combination of the aforementioned methods with or without traditional microfabrication methods discussed earlier.

In the second step (S1.2), the extraction tape 703 may be attached on the planar substrate 701 using for example a fully automated or semi-automated tape mounter (i.e. tape applicator), a manual tape applicator, or any other tool which is able to provide sufficient conformability of the extraction tape 703 onto the planar 701 substrate, the conformability meaning lack of, or very small amount of, air voids (or air bubbles) at the interface of the planar substrate 701 and the extraction tape 703.

In some embodiments it might be beneficial to attach the extraction tape 703 on the planar substrate 701 and trim the extraction tape 703 to a smaller shape than a dicing frame for example along the edge of the planar substrate. The extraction tape 703 on the planar substrate 701 back side might be trimmed due to later process requirements like those of a wafer taper or a die handling equipment.

In the third step (S1.3), the dicing tape may be attached on the radiation extraction coating 300, 404 using any tool which is able to provide sufficient conformability of the dicing tape 704 onto the extraction coating. In embodiments, the extraction tape and the dicing tape are attached to the planar substrate 701 by a same device, for example any of the devices mentioned above in relation to step S1.2. In alternative embodiments, the extraction tape and the dicing tape are attached to the planar substrate in separate attaching steps. For example, it is possible that the extraction tape 703 and the dicing tape 704 are attached to the planar substrate 701 in separate steps using the same tool, or in separate steps using separate tools. The former option may be beneficial in case where the same tool is suitable for both tapes 703, 704, and the latter option may be beneficial in case where one tool is more suitable for attaching the extraction tape 703, and another tool is more suitable for attaching the dicing tape 704. It is also possible, that the extraction tape 703 and the dicing tape 704 are attached together prior to attaching to the planar substrate 701

In the fourth step (S1.4), the cutting (i.e. dicing) through the planar substrate 701 and radiation extraction coating 300, 404 may be performed by any wafer dicing (i.e. die singulation) tool capable of controlling the cut 705 depth such that the radiation extraction coating 300, 404 is cut, but the dicing tape 704 remains intact. It may be preferrable for example that the cut 705 has sufficient depth to penetrate also part of the dicing tape 704 to ensure that the dies are reliably separated. Non-limiting examples of possible cutting tools comprise mechanical dicing (e.g. blade saw dicing), laser dicing (e.g. water jet guided laser dicing) or plasma dicing tool.

In the fifth step (S1.5), the releasing of the dies 706 from the dicing tape 704 may be performed using for example manual die release (i.e. removal) tools, pick-and-place tools, or any other automatic or semiautomatic tool with sufficient fidelity to release the die from the dicing tape 704 without releasing the extraction tape 703 from the planar substrate. Furthermore, if the dicing tape 704 comprises an adhesive layer with an UV-sensitive adhesive (i.e. an adhesive for which the adhesive strength can be reduced by applying UV-radiation), it is possible that an additional step for UV-exposure is provided before releasing the die from the dicing tape 704. Similarly, if the dicing tape comprises a heat sensitive adhesive (i.e. an adhesive for which the adhesive strength can be reduced by applying heat), it is possible that an additional step for heating is provided before releasing the die from the dicing tape 704.

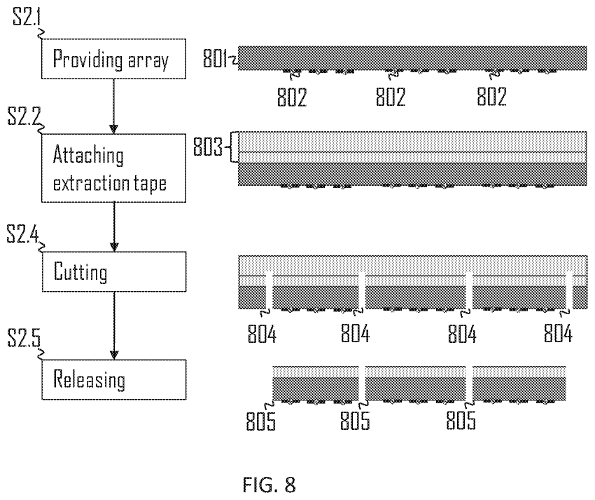

According to an aspect of the invention exemplified in FIG. 8 there is provided a method of manufacturing the on-chip antenna of above embodiments, wherein the method comprises
providing (S2.1) at least one array of radiating elements on a first surface of a planar substrate,
attaching (S2.2) an extraction tape on an opposite surface of the planar substrate to form a radiation extraction coating, the extraction tape having a base layer of polymeric material and an adhesive layer between the planar substrate and the base layer of polymeric material, wherein a portion of the extraction tape serves as a dicing tape,
cutting (S2.3) through the planar substrate and a portion of the thickness of the radiation extraction tape in order to form dies having the radiation extraction coating; and
releasing (S2.4) the dies having the radiation extraction coating from the portion of the extraction tape that serves as the dicing tape.

In the first step (S2.1), the at least one array of radiating elements 802 may be provided as explained above in relation to FIG. 7.

In the second step (S2.2), the extraction tape 803 may be attached on the planar substrate 801 as explained above in relation to FIG. 7.

In the third step (S.2.3) the cutting through the planar substrate 801 and a portion of the thickness of the extraction tape 803 may be performed by any wafer dicing (i.e. die singulation) tool capable of controlling the cut 804 depth such that the portion of the extraction tape 803 serving as radiation extraction coating 300, 404 is cut, but the portion of the extraction tape 803 serving as dicing tape remains intact. Non-limiting examples of possible cutting tools are mentioned above in relation to FIG. 7.

In the fourth step (S2.4), the releasing of the dies 805 from the portion of the radiation extraction coating 300, 404 serving as a dicing tape may be performed using for example manual die release (i.e. removal) tools, pick-and-place tools, or any other automatic or semiautomatic tool with sufficient fidelity to release the die from the portion of the extraction tape 803 serving as a dicing tape without releasing the portion of the extraction tape 803 serving as the radiation extraction coating from the planar substrate.

The description and the related drawings are only intended to illustrate the principles of the present invention by means of examples. Various alternative embodiments, variations and changes are obvious to a person skilled in the art on the basis of this description. The present invention is not intended to be limited to the examples described herein but the invention may vary within the scope and spirit of the appended claims.

1. An on-chip antenna comprising:
an array of radiating elements arranged on a first surface of a planar substrate to radiate electromagnetic radiation at a frequency in a range from about 100 GHz to 1 THz; and
a radiation extraction coating arranged on an opposite surface of the planar substrate,
wherein a thickness and a refractive index of the radiation extraction coating are selected such that the electromagnetic radiation reflected from an interface between the planar substrate and the radiation extraction coating and the electromagnetic radiation reflected from an interface between the radiation extraction coating and a surrounding medium are minimized, and are substantially out of phase and cancel each other in the substrate at least partially, resulting in a higher extraction of the electromagnetic radiation to the surrounding medium.

2. The on-chip antenna of claim 1, wherein the radiation extraction coating is formed by an extraction tape comprising a base layer of polymeric material and an adhesive layer between the planar substrate and the layer of polymeric material.

3. The on-chip antenna of claim 2, wherein the extraction tape serves also as a dicing tape.

4. The on-chip antenna of claim 2, wherein the radiation extraction coating is formed by the extraction tape applied on the planar substrate prior to applying a dicing tape during a manufacturing process, the extraction tape being left on the surface of the planar substrate after dicing.

5. The on-chip antenna of claim 4, wherein the radiation extraction coating formed by the extraction tape is cut through to the dicing tape during the manufacturing process.

6. The on-chip antenna of claim 2, wherein the polymeric material of the base layer comprises polypropene, polyimide or polyethylene.

7. The on-chip antenna of claim 2, wherein the polymeric material of the base layer comprises a composite of a polymer and a filler material.

8. The on-chip antenna of claim 1, wherein the thickness of the radiation extraction coating is within a tolerance of an odd multiple of a quarter wavelength of the electromagnetic radiation in the radiation extraction coating, the tolerance being preferably less than ±20%, more preferably ±10%, and even more preferably ±5%.

9. The on-chip antenna of claim 1, wherein the refractive index of the radiation extraction coating is within a tolerance of a geometric mean of a refractive index of the planar substrate and a refractive index of the surrounding medium, the tolerance being preferably less than ±20%, more preferably ±10%, and even more preferably ±5%.

10. The on-chip antenna of claim 1, wherein the array of radiating elements comprises a phased array of radiating elements.

11. The on-chip antenna of claim 1, wherein distance between each radiating element of the array of radiating elements is no more than half of the wavelength of the electromagnetic waves.

12. The on-chip antenna of claim 1, wherein the planar substrate comprises a layer of semiconductive material or a stack of materials with at least one layer of semiconductive material.

13. The on-chip antenna of claim 1, wherein the planar substrate comprises a layer of insulating material.

14. The on-chip antenna of claim 1, wherein the planar substrate comprises a Silicon on Sapphire (SOS) structure or a Silicon on Insulator (SOI) structure.

15. A method of manufacturing an on-chip antenna array comprising:
an array of radiating elements arranged on a first surface of a planar substrate to radiate electromagnetic radiation at a frequency in a range from about 100 GHz to 1 THz; and
a radiation extraction coating arranged on an opposite surface of the planar substrate,
wherein a thickness and a refractive index of the radiation extraction coating are selected such that the electromagnetic radiation reflected from an interface between the planar substrate and the radiation extraction coating and the electromagnetic radiation reflected from an interface between the radiation extraction coating and a surrounding medium are minimized, and are substantially out of phase and cancel each other in the substrate at least partially, resulting in a higher extraction of the electromagnetic radiation to the surrounding medium,
wherein the method comprises:
providing the planar substrate having at least the array of radiating elements on the first surface;
attaching an extraction tape on the opposite surface of the planar substrate to form the radiation extraction coating, the extraction tape having a base layer of polymeric material and an adhesive layer between the planar substrate and the base layer of polymeric material;
attaching a dicing tape on the radiation extraction coating;
cutting through the planar substrate and the radiation extraction coating in order to form dies having the radiation extraction coating; and
releasing the dies having the radiation extraction coating from the dicing tape.

16. The method of claim 15, wherein the extraction tape and the dicing tape are attached to the planar substrate by a same device.

17. The method of claim 15, wherein the extraction tape and the dicing tape are attached to the planar substrate in separate attaching steps.

18. The method of claim 16, wherein the extraction tape and the dicing tape are attached together prior to attaching to the planar substrate.

19. A method of manufacturing an on-chip antenna array comprising:
an array of radiating elements arranged on a first surface of a planar substrate to radiate electromagnetic radiation at a frequency in a range from about 100 GHz to 1 THz; and
a radiation extraction coating arranged on an opposite surface of the planar substrate,
wherein a thickness and a refractive index of the radiation extraction coating are selected such that the electromagnetic radiation reflected from an interface between the planar substrate and the radiation extraction coating and the electromagnetic radiation reflected from an interface between the radiation extraction coating and a surrounding medium are minimized, and are substantially out of phase and cancel each other in the substrate at least partially, resulting in a higher extraction of the electromagnetic radiation to the surrounding medium,
wherein the method comprises:
providing the planar substrate having at least the array of radiating elements on the first surface;
attaching an extraction tape on the opposite surface of the planar substrate to form the radiation extraction coating, the extraction tape having a base layer of polymeric material and an adhesive layer between the planar substrate and the base layer of polymeric material, wherein a portion of the extraction tape serves as a dicing tape;
cutting through the planar substrate and a portion of a thickness of the extraction tape in order to form dies having the radiation extraction coating; and
releasing the dies having the radiation extraction coating from the portion of the extraction tape that serves as the dicing tape.

20. An extraction tape to form a radiation extraction coating for use in an on-chip antenna array comprising:
an array of radiating elements arranged on a first surface of a planar substrate to radiate electromagnetic radiation at a frequency in a range from about 100 GHz to 1 THz; and
the radiation extraction coating arranged on an opposite surface of the planar substrate,
wherein a thickness and a refractive index of the radiation extraction coating are selected such that the electromagnetic radiation reflected from an interface between the planar substrate and the radiation extraction coating and the electromagnetic radiation reflected from an interface between the radiation extraction coating and a surrounding medium are minimized, and are substantially out of phase and cancel each other in the substrate at least partially, resulting in a higher extraction of the electromagnetic radiation to the surrounding medium, and
wherein the extraction tape comprises a base layer of polymeric material and an adhesive layer.

21. The extraction tape of claim 20, wherein the extraction tape is a dicing tape.
